(19) United States
(12) Patent Application Publication
(10) Pub. No.: US 2015/0331338 A1
(43) Pub. Date: Nov. 19, 2015

(54) Substrate Support for a Lithographic Apparatus and Lithographic Apparatus

(71) Applicant: ASML Netherlands B.V., Veldhoven (NL)

(72) Inventors: Erik Johan ARLEMARK, Waalre (NL); Andrianus Hendrik KOEVOETS, Mierlo (NL); Raymond Wilhelmus Louis LAFARRE, Helmond (NL); Nicolaas TEN KATE, Almkerk (NL); Carlo Cornelis Maria LUIJTEN, Duizel (NL); Han-Kwang NIENHUYS, Utrecht (NL)

(73) Assignee: ASML NETHERLANDS B.V., Veldhoven (NL)

(21) Appl. No.: 14/651,567

(22) PCT Filed: Nov. 26, 2013
(86) PCT No.: PCT/EP2013/074742

§ 371 Date: Jun. 11, 2015

Related U.S. Application Data
(60) Provisional application No. 61/873,806, filed on Sep. 4, 2013.
(60) Provisional application No. 61/738,344, filed on Dec. 17, 2012.

(51) Int. Cl. G03F 7/20

(52) U.S. Cl. CPC G03F 7/70875

(57) ABSTRACT

Disclosed is a substrate support for an apparatus of the type which projects a beam of EUV radiation onto a target portion of a substrate (400). The substrate support comprises a substrate table constructed to hold the substrate, a support block (420) for supporting the substrate table, and a cover plate (450′) disposed around the substrate table. The top surface of the cover plate and the top surface of a substrate mounted on the substrate table are all substantially at the same level. At least one sensor unit (430) is located on the substrate support and its top surface is also at the same level as that of the cover plate and substrate. Also disclosed is an EUV lithographic apparatus comprising such a substrate support.

### CROSS-REFERENCE TO RELATED APPLICATIONS

This application claims the benefit of U.S. provisional application 61/738,344 which was filed on Dec. 17, 2012 and of U.S. provisional application 61/873,806 which was filed on Sep. 4, 2013, and which is incorporated herein in its entirety by reference.

### FIELD

The present invention relates to a lithographic apparatus and a substrate support for a Lithographic Apparatus.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned.

Lithography is widely recognized as one of the key steps in the manufacture of ICs and other devices and/or structures. However, as the dimensions of features made using lithography become smaller, lithography is becoming a more critical factor for enabling miniature IC or other devices and/or structures to be manufactured.

A theoretical estimate of the limits of pattern printing can be given by the Rayleigh criterion for resolution as shown in equation (1):

$$CD = {k}_{1} * \frac{λ}{NA} \qquad ( 1 )$$

where λ is the wavelength of the radiation used, NA is the numerical aperture of the projection system used to print the pattern, kl1 is a process dependent adjustment factor, also called the Rayleigh constant, and CD is the feature size (or critical dimension) of the printed feature. It follows from equation (1) that reduction of the minimum printable size of features can be obtained in three ways: by shortening the exposure wavelength λ, by increasing the numerical aperture NA or by decreasing the value of k1.

In order to shorten the exposure wavelength and, thus, reduce the minimum printable size, it has been proposed to use an extreme ultraviolet (EUV) radiation source. EUV radiation is electromagnetic radiation having a wavelength within the range of 5-20 nm, for example within the range of 13-14 nm. It has further been proposed that EUV radiation with a wavelength of less than 10 nm could be used, for example within the range of 5-10 nm such as 6.7 nm or 6.8 nm. Such radiation is termed extreme ultraviolet radiation or soft x-ray radiation. Possible sources include, for example, laser-produced plasma sources, discharge plasma sources, or sources based on synchrotron radiation provided by an electron storage ring.

EUV radiation may be produced using a plasma. A radiation system for producing EUV radiation may include a laser for exciting a fuel to provide the plasma, and a source collector apparatus for containing the plasma. The plasma may be created, for example, by directing a laser beam at a fuel, such as particles of a suitable material (e.g., tin), or a stream of a suitable gas or vapor, such as Xe gas or Li vapor. The resulting plasma emits output radiation, e.g., EUV radiation, which is collected using a radiation collector. The radiation collector may be a mirrored normal incidence radiation collector, which receives the radiation and focuses the radiation into a beam. The source collector apparatus may include an enclosing structure or chamber arranged to provide a vacuum environment to support the plasma. Such a radiation system is typically termed a laser produced plasma (LPP) source.

The chamber containing the projection optics and the environment containing the wafer table and support may be separated by a gas lock mechanism, which prevents contaminants from the wafer table environment from entering the projection optics chamber. A gas flow is emitted from the gas lock mechanism onto the wafer stage below, which induces a heat load upon the wafer stage. This heat load may not always be constant over the wafer stage, and can change depending upon the position of the wafer stage. For example, the heat load can be seen to be higher when the gas lock mechanism is above a sensor (e.g., a transmission image sensor TIS plate).

### SUMMARY

It is desirable to reduce the heat load resultant from gasses emitted from a gas lock mechanism on elements of a wafer stage, such as a sensor and/or wafer itself.

A first embodiment provides a substrate support for an apparatus of the type which projects a beam of radiation having a wavelength in the EUV range or smaller, onto a target portion of a substrate, the substrate support comprising: a substrate table constructed to hold a substrate, a support block for supporting the substrate table, at least one sensor unit, and a cover plate disposed around the substrate table and the sensor unit(s) such that the top surface of the cover plate, the top surface of the sensor unit(s) and the top surface of a substrate when mounted on the substrate table are all substantially at the same level. By EUV range herein is meant electromagnetic radiation having a wavelength within the range of 5-20 nm.

Another embodiment provides for a lithographic apparatus comprising: The substrate support of the first aspect, a projection system within a projection chamber and configured to project a beam of EUV radiation onto a target portion of the substrate supported by the substrate support, a gas lock mechanism for restricting contaminants entering the projection chamber, while transmitting the beam of EUV radiation from the projection chamber.

Another embodiment provides for an apparatus comprising:

a substrate support comprising:

a substrate table constructed to hold a substrate;

a support block configured to support the substrate table;

at least one sensor unit; and

a cover plate disposed around the substrate table and the at least one sensor unit, the cover plate being located and configured to cause an increased resistance to a gas flow upon the substrate table;

an optical system within a chamber; and

a gas lock mechanism for restricting contaminants entering the chamber.

Lithographic apparatus here is any apparatus used in a lithographic process, including for example, those used for metrology/inspection.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present invention and, together with the description, further serve to explain the principles of the invention and to enable a person skilled in the relevant art(s) to make and use the invention. Embodiments of the invention are described, by way of example only, with reference to the accompanying drawings, in which:

FIG. 1 depicts schematically a lithographic apparatus having reflective projection optics, according to an embodiment of the invention;

FIG. 2 is a more detailed view of the apparatus of FIG. 1; and

FIG. 3 schematically depicts an alternative source arrangement to that depicted in FIG. 2;

FIG. 4a shows an example of a known substrate support arrangement;

FIG. 4b illustrates the gas flow with the substrate support arrangement of FIG. 4a;

FIGS. 5a and 5b show The substrate support arrangement according to an embodiment of the invention;

FIGS. 6a and 6b show substrate support arrangements according to further embodiments of the invention;

FIGS. 7a, 7b and 7c show substrate support arrangements according to yet further embodiments of the invention;

FIGS. 8a, 8b and 8c show The substrate support arrangement according to a yet further embodiment of the invention; and

FIGS. 9a and 9b show substrate support arrangements according to yet further embodiments of the invention.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements.

### DETAILED DESCRIPTION OF EXEMPLARY EMBODIMENTS

This specification discloses one or more embodiments that incorporate the features of this invention. The disclosed embodiment(s) merely exemplify the invention. The scope of the invention is not limited to the disclosed embodiment(s). The invention is defined by the claims appended hereto.

The embodiment(s) described, and references in the specification to “one embodiment”, “an embodiment”, “an example embodiment”, etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals, and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

Before describing such embodiments in more detail, however, it is instructive to present an example environment in which embodiments of the present invention may be implemented.

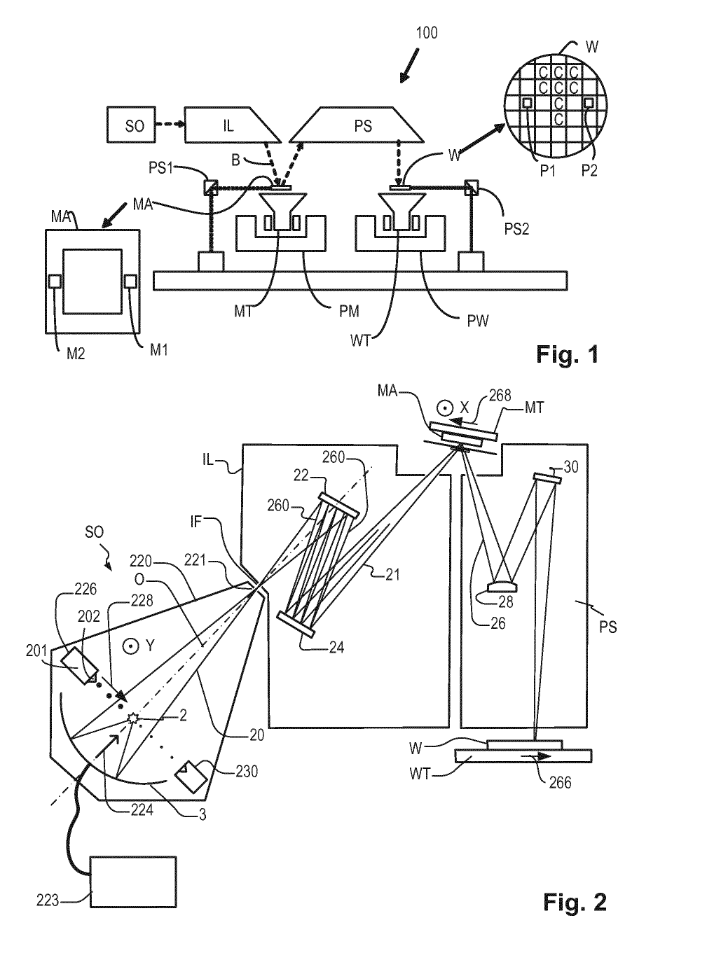

FIG. 1 schematically shows a lithographic apparatus LAP including a source collector module SO according to an embodiment of the invention. The apparatus comprises: an illumination system (illuminator) IL configured to condition a radiation beam B (e.g., EUV radiation); a support structure (e.g., a mask table) MT constructed to support a patterning device (e.g., a mask or a reticle) MA and connected to a first positioner PM configured to accurately position the patterning device; a substrate table (e.g., a wafer table) WT constructed to hold a substrate (e.g., a resist-coated wafer) W and connected to a second positioner PW configured to accurately position the substrate; and a projection system (e.g., a reflective projection system) PS configured to project a pattern imparted to the radiation beam B by patterning device MA onto a target portion C (e.g., comprising one or more dies) of the substrate W.

The illumination system may include various types of optical components, such as refractive, reflective, magnetic, electromagnetic, electrostatic or other types of optical components, or any combination thereof, for directing, shaping, or controlling radiation.

The support structure MT holds the patterning device MA in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system.

The term “patterning device” should be broadly interpreted as referring to any device that can be used to impart a radiation beam with a pattern in its cross-section such as to create a pattern in a target portion of the substrate. The pattern imparted to the radiation beam may correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The projection system, like the illumination system, may include various types of optical components, such as refractive, reflective, magnetic, electromagnetic, electrostatic or other types of optical components, or any combination thereof, as appropriate for the exposure radiation being used, or for other factors such as the use of a vacuum. It may be desired to use a vacuum for EUV radiation since other gases may absorb too much radiation. A vacuum environment may therefore be provided to the whole beam path with the aid of a vacuum wall and vacuum pumps.

As here depicted, the apparatus is of a reflective type (e.g., employing a reflective mask).

The lithographic apparatus may be of a type having two (dual stage) or more substrate tables (and/or two or more mask tables). In such “multiple stage” machines the additional tables may be used in parallel, or preparatory steps may be carried out on one or more tables while one or more other tables are being used for exposure.

Referring to FIG. 1, the illuminator IL receives an extreme ultra violet radiation beam from the source collector module SO. Methods to produce EUV light include, but are not necessarily limited to, converting a material into a plasma state that has at least one element, e.g., xenon, lithium or tin, with one or more emission lines in the EUV range. In one such method, often termed laser produced plasma (“LPP”) the required plasma can be produced by irradiating a fuel, such as a droplet, stream or cluster of material having the required line-emitting element, with a laser beam. The source collector module SO may be part of an EUV radiation system including a laser, not shown in FIG. 1, for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser is not considered to form part of the lithographic apparatus and the radiation beam is passed from the laser to the source collector module with the aid of a beam delivery system comprising, for example, suitable directing mirrors and/or a beam expander. In other cases the source may be an integral part of the source collector module, for example when the source is a discharge produced plasma EUV generator, often termed as a DPP source.

The illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross-section.

The radiation beam B is incident on the patterning device (e.g., mask) MA, which is held on the support structure (e.g., mask table) MT, and is patterned by the patterning device. After being reflected from the patterning device (e.g., mask) MA, the radiation beam B passes through the projection system PS, which focuses the beam onto a target portion C of the substrate W. With the aid of the second positioner PW and position sensor PS2 (e.g., an interferometric device, linear encoder or capacitive sensor), the substrate table WT can be moved accurately, e.g., so as to position different target portions C in the path of the radiation beam B. Similarly, the first positioner PM and another position sensor PS1 can be used to accurately position the patterning device (e.g., mask) MA with respect to the path of the radiation beam B. Patterning device (e.g., mask) MA and substrate W may be aligned using mask alignment marks M1, M2 and substrate alignment marks P1, P2.

The depicted apparatus could be used in at least one of the following modes:

1. In step mode, the support structure (e.g., mask table) MT and the substrate table WT are kept essentially stationary, while an entire pattern imparted to the radiation beam is projected onto a target portion C at one time (i.e., a single static exposure). The substrate table WT is then shifted in the X and/or Y direction so that a different target portion C can be exposed.

2. In scan mode, the support structure (e.g., mask table) MT and the substrate table WT are scanned synchronously while a pattern imparted to the radiation beam is projected onto a target portion C (i.e., a single dynamic exposure). The velocity and direction of the substrate table WT relative to the support structure (e.g., mask table) MT may be determined by the (de-)magnification and image reversal characteristics of the projection system PS.

3. In another mode, the support structure (e.g., mask table) MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable minor array of a type as referred to above.

Combinations and/or variations on the above described modes of use or entirely different modes of use may also be employed.

FIG. 2 shows the apparatus 100 in more detail, including the source collector module SO, the illumination system IL, and the projection system PS. The source collector module SO is constructed and arranged such that a vacuum environment can be maintained in an enclosing structure 220 of the source collector module SO. The systems IL and PS are likewise contained within vacuum environments of their own. An EUV radiation emitting plasma 2 may be formed by a laser produced LPP plasma source. The function of source collector module SO is to deliver EUV radiation beam 20 from the plasma 2 such that it is focused in a virtual source point. The virtual source point is commonly referred to as the intermediate focus (IF), and the source collector module is arranged such that the intermediate focus IF is located at or near an aperture 221 in the enclosing structure 220. The virtual source point IF is an image of the radiation emitting plasma 2.

From the aperture 221 at the intermediate focus IF, the radiation traverses the illumination system IL, which in this example includes a facetted field mirror device 22 and a facetted pupil mirror device 24. These devices form a so-called “fly's eye” illuminator, which is arranged to provide a desired angular distribution of the radiation beam 21, at the patterning device MA, as well as a desired uniformity of radiation intensity at the patterning device MA. Upon reflection of the beam 21 at the patterning device MA, held by the support structure (mask table) MT, a patterned beam 26 is formed and the patterned beam 26 is imaged by the projection system PS via reflective elements 28, 30 onto a substrate W held by the wafer stage or substrate table WT. To expose a target portion C on substrate W, pulses of radiation are generated on substrate table WT and mask table MT performs synchronized movements 266, 268 to scan the pattern on patterning device MA through the slit of illumination.

Each system IL and PS is arranged within its own vacuum or near-vacuum environment, defined by enclosing structures similar to enclosing structure 220. More elements than shown may generally be present in illumination system IL and projection system PS. Further, there may be more mirrors present than those shown in the Figures. For example there may be one to six additional reflective elements present in the illumination system IL and/or the projection system PS, besides those shown in FIG. 2.

Considering source collector module SO in more detail, laser energy source comprising laser 223 is arranged to deposit laser energy 224 into a fuel, such as xenon (Xe), tin (Sn) or lithium (Li), creating the highly ionized plasma 2 with electron temperatures of several 10's of eV. Higher energy EUV radiation may be generated with other fuel materials, for example Tb and Gd. The energetic radiation generated during de-excitation and recombination of these ions is emitted from the plasma, collected by a near-normal incidence collector 3 and focused on the aperture 221. The plasma 2 and the aperture 221 are located at first and second focal points of collector CO, respectively.

Although the collector 3 shown in FIG. 2 is a single curved mirror, the collector may take other forms. For example, the collector may be a Schwarzschild collector having two radiation collecting surfaces. In an embodiment, the collector may be a grazing incidence collector which comprises a plurality of substantially cylindrical reflectors nested within one another. The grazing incidence collector may be suited for use in a DPP source.

To deliver the fuel, which for example is liquid tin, a droplet generator 226 is arranged within the enclosure 220, arranged to fire a high frequency stream 228 of droplets towards the desired location of plasma 2. In operation, laser energy 224 is delivered in a synchronism with the operation of droplet generator 226, to deliver impulses of radiation to turn each fuel droplet into a plasma 2. The frequency of delivery of droplets may be several kilohertz, for example 50 kHz. Laser energy 224 may be delivered in at least two pulses to enhance conversion efficiency: a pre pulse with limited energy is delivered to the droplet before it reaches the plasma location, in order to vaporize the fuel material into a small cloud, and then a main pulse of laser energy 224 is delivered to the cloud at the desired location, to generate the plasma 2. The pre pulse and main pulse may be delivered from the same laser source or from different laser sources. A trap 230 is provided on the opposite side of the enclosing structure 220, to capture fuel that is not, for whatever reason, turned into plasma.

In an alternative configuration (not illustrated) the EUV radiation may be generated by causing a partially ionized plasma of an electrical discharge to collapse onto an optical axis (e.g., via the pinch effect). This source may be referred to as a discharge produced plasma (DPP) source. Partial pressures of for example 10 Pa of Xe, Li, Sn vapor or any other suitable gas or vapor may be used to generate the EUV radiation emitting plasma.

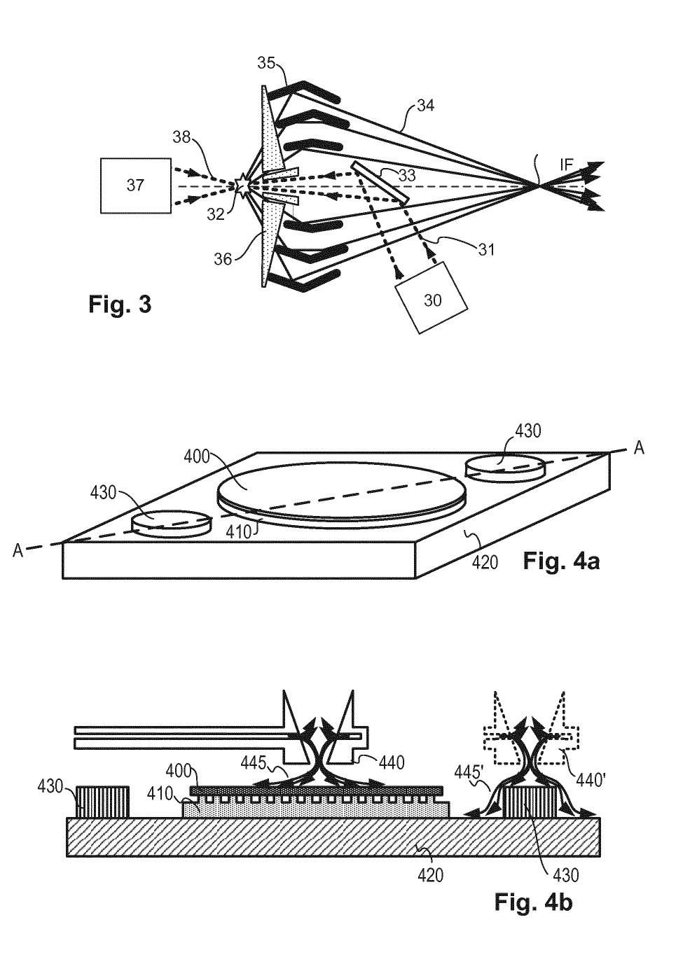

FIG. 3 shows an alternative LPP source arrangement which may be used in place of that illustrated in FIG. 2. A main difference is that the main pulse laser beam is directed onto the fuel droplet from the direction of the intermediate focus point IF, such that the collected EUV radiation is that which is emitted generally in the direction from which the main laser pulse was received. FIG. 3 shows the main laser 30 emitting a main pulse beam 31 delivered to a plasma generation site 32 via at least one optical element (such as a lens or folding minor) 33. The EUV radiation 34 is collected by a grazing incidence collector 35 such as the collectors used in discharge produced plasma (DPP) sources. Also shown is a debris trap 36, which may comprise one or more stationary foil traps and/or a rotating foil trap, and a pre pulse laser 37 operable to emit a pre pulse laser beam 38.

As the skilled reader will know, reference axes X, Y and Z may be defined for measuring and describing the geometry and behavior of the apparatus, its various components, and the radiation beams 20, 21, 26. At each part of the apparatus, a local reference frame of X, Y and Z axes may be defined. The Z axis broadly coincides with the direction optical axis O at a given point in the system, and is generally normal to the plane of a patterning device (reticle) MA and normal to the plane of substrate W. In the source collector module, the X axis coincides broadly with the direction of fuel stream 228, while the Y axis is orthogonal to that, pointing out of the page as indicated in FIG. 2. On the other hand, in the vicinity of the support structure MT that holds the reticle MA, the X axis is generally transverse to a scanning direction aligned with the Y axis. For convenience, in this area of the schematic diagram FIG. 2, the X axis points out of the page, again as marked. These designations are conventional in the art and will be adopted herein for convenience. In principle, any reference frame can be chosen to describe the apparatus and its behavior.

Numerous additional components critical to operation of the source collector module and the lithographic apparatus as a whole are present in a typical apparatus, though not illustrated here. These include arrangements for reducing or mitigating the effects of contamination within the enclosed vacuum, for example to prevent deposits of fuel material damaging or impairing the performance of collector 3 and other optics. Other features present but not described in detail are all the sensors, controllers and actuators involved in controlling of the various components and sub-systems of the lithographic apparatus.

When using a laser produced plasma (LPP) source or discharge produced plasma (DPP) source, contamination may be produced in the form of debris such as fast ions and/or neutral particles (for example Sn (tin)). Such debris may build up on the reflective surface(s) of the collector 3, causing the collector to lose reflectivity and thereby reducing the efficiency of the collector. Contamination by debris may also cause other reflective components of the lithographic apparatus (for example mirrors 22, 24, 28, 30 or patterning device MA) to lose reflectivity over time. The throughput of the lithographic apparatus is dependent upon the intensity of EUV radiation which is incident on a substrate being exposed. Any reduction of reflectivity which arises due to the build up of debris on the collector or other reflective surfaces of the lithographic apparatus may reduce the throughput of the lithographic apparatus.

A gas lock mechanism such as a Dynamic Gas Lock (DGL) is a shared opening between the otherwise separated Projection Optics (PO) Chamber environment (that is the chamber comprising the optics for Projection System PS in FIG. 2) and the Wafer Stage (WS) environment. The gas lock mechanism, further on referred to as the DGL may have a hollow body including a first and a second end, the body extending substantially around a path of the EUV radiation beam from the first to the second end. The hollow body may be in communication with a gas flow unit configured to produce a gas flow within the body. Using such a gas flow unit, a gas flow may be provided to the hollow body, the gas flow exiting the hollow body via both the first and second end, i.e. towards both the PO Chamber environment and the WS environment. As a result, the gas inside the hollow body provides in a gas-type barrier between the PO Chamber environment and the WS environment.

The projection system may consist of reflective optics (e.g., mirrors), having a surface flatness that is controlled at an atomic level. Such optics may easily be damaged by molecules entering the projection optics chamber and contaminating the surface of the optics. Therefore, although both the PO chamber and the wafer stage environment may be under very high vacuum levels during operation (e.g. in a range of 2 to 15 Pa), the projection optics PO chamber may be maintained at a higher pressure than wafer stage environment to prevent contaminants from the wafer stage (e.g., out-gassing from resist) entering the projection optics chamber. Alternatively, contaminants may be prevented from entering the wafer stage environment by injecting gas into the DGL. The gas employed in the DGL should be such that it does not substantially absorb the radiation in the projection beam (e.g., EUV), while having a substantially low diffusion coefficient for contaminants. Examples of such gases that may be used in DGLs include Hydrogen, Argon, Krypton and Helium.

The DGL generates a heat load to both the wafer (and wafer table—often referred to as a clamp) and to any neighboring sensor support/plate, such as the transmission image sensor (TIS) plate, depending on which of the two is positioned under the DGL opening. The TIS plate is a sensor unit which comprises one or more sensors and markers for use in a transmission image sensing system, used for accurate positioning of the wafer relative to the position of the projection lens system PS and the mask MA of the lithographic system. The root cause of this heat load is the impact of the gas onto the surface, i.e. the aforementioned gas flow of the gas flow unit towards the WS environment. The absolute heat load generated by this gas depends on the flow rate and temperature of the gas impacting the wafer or the TIS plate, respectively. This flow rate depends on the distribution of DGL flow between a flow towards the projection optics side (typically an upward flow) and a flow towards the wafer stage side (typically a downward flow).

The positioner PW and wafer table WT arrangement of FIG. 1 may comprise a wafer table supported by a support block, with actuators underneath the support block for moving the support block and wafer table. In an embodiment the support block may comprise a block of glass with a reflective coating to reflect laser beams for position sensing, commonly referred to as a mirror block. The “f-factor”, is a ratio of flow rate from DGL to wafer stage compared to the flow rate injected into the DGL. This f-factor, and hence the flow distribution between projection optics side and wafer stage side, depends on the flow resistance experienced by the downward (WS side) flow, and consequently on the support block position.

As can be seen in FIG. 4a, the TIS plate 430 and wafer/wafer clamp protrude from the support block surface. There are a number of reasons why this may appear preferable. Such a design leads to a lower flow resistance and therefore a higher gas flow rate down from the DGL, and consequently a better rejection of contamination. Also Modules (sensors, cabling, and tubing) are easy to access and service. However, because both the TIS plate and wafer/wafer clamp protrude from the support block surface, and the TIS plate is smaller than the wafer table, the DGL flow which is directed downward will be significantly larger when the TIS is positioned under DGL than when the wafer is positioned under DGL. This is because of the smaller flow resistance experienced by the flow while the DGL is above the TIS plate. A consequence of this is a large heat load on the TIS plate, which disturbs alignment and lot correction.

FIGS. 4a and 4b illustrate this issue. FIG. 4a shows an example of a known EUV wafer stage arrangement. It comprises a wafer 400 on wafer table 410, which is mounted on support block (or support block) 420. Also shown on the support block 420 is TIS plate 430. While TIS sensor plates are shown here for illustration, the concepts herein are not limited to any particular sensor type whatsoever, and may include arrangements with different sensor units in place of one or both of TIS plates 430. Such sensor units may thus be coupled to the support block 420 and may be even integrated in the support block.

FIG. 4b shows the arrangement of FIG. 4a (in cross section through AA), with DGL 440 in a first position (solid lines) over wafer 400, and the DGL 440′ in a second position (broken lines) over TIS plate 430. The arrows 445 represent the downward (WS side) flow from the DGL when the DGL is located over wafer 400. The arrows 445′ represent the downward (WS side) flow from the DGL when the DGL is located over TIS plate 430. It can be seen that flow pattern 445 is different to that of flow pattern 445′. This results in a greater flow resistance when the DGL 440 is over the wafer 400 compared to when it is over the TIS plate 430.

A similar situation arises when a wafer edge is positioned below the DGL. The flow resistance is at the wafer edge is reduced compared to the center of the wafer, therefore increasing the heat load. In fact, the mass flow to the wafer stage and thus the heat load on the wafer is ‘die’ dependent, which leads to dynamic non-uniform heat loads during exposure.

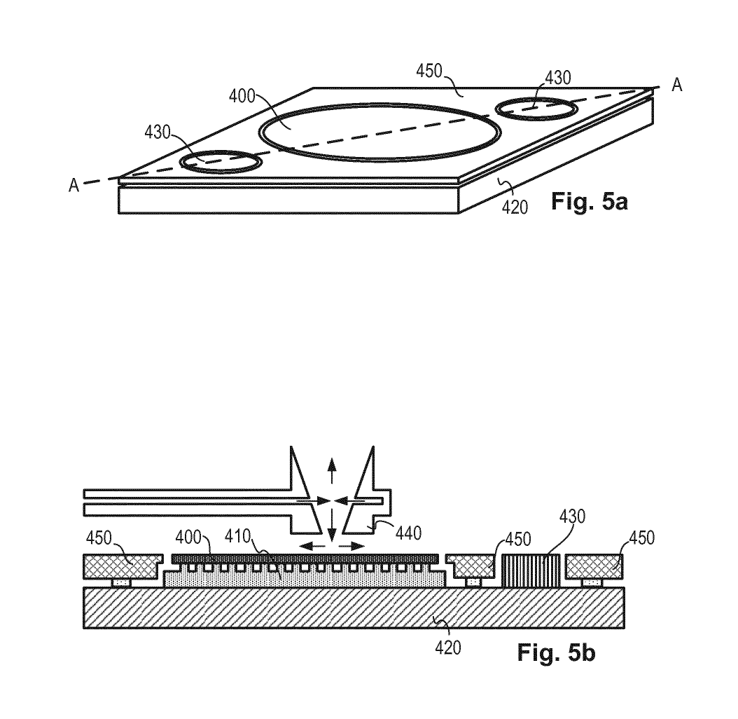

FIGS. 5a and 5b show a chuck arrangement which attempts to address the above issues. Such an arrangement is represented by positioner PW and support structure WT in FIG. 1. This shows a chuck arrangement with the addition of a cover plate 450 on the support block 420. The cover plate 450 comprises openings for the wafer table 410 and TIS plates 430. The top surface of the cover plate 450 may be level with the TIS plates 430 and wafer 400, in order to level off the top surface of the support block assembly. The cover plate 450 is formed separately to, and is supported by, the support block 420. The arrows shown of FIG. 5b illustrate typical DGL 440 gas flow. The term “cover” for plate 450 herein has thus the meaning to cover portions of the wafer stage such as to surround wafer stage elements (sensors, wafer when present).

The addition of cover plate 450 helps equalize the flow resistance encountered when the TIS is under DGL 440 and when the wafer (whether center or edge) is under DGL 440. It does this by increasing the flow resistance encountered when the TIS plate 430 is under DGL 440, compared to the arrangement of FIG. 4b, resulting in a more homogeneous f-factor over the whole top surface of the support block assembly. As a consequence, the flow at the TIS decreases, giving rise to a smaller heat load effect on the TIS plate 430, which results in improved alignment accuracy (thus benefiting overlay).

The cover plate also prevents DGL 440 gas flow impinging directly on the top surface of support block 420 and side walls of the wafer table 410 and TIS plate 430 when the DGL 440 is moved from wafer 400 to TIS plate 430. This helps prevent various dynamic edge effects and reduce the heat transfer towards these edges.

A more stable flow downwards also results in a more stable flow towards the projection optics chamber, which stabilizes projection optics chamber temperatures and may reduce contamination (contaminants are released from surfaces when flow changes occur). Moreover, the flow may be more predictable, leading to improved designs.

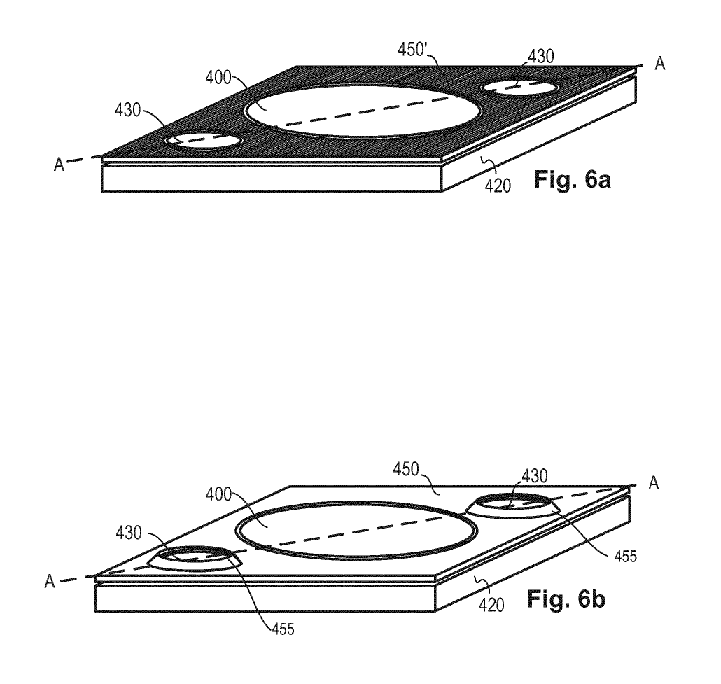

In addition to adding a flat cover plate, it is also possible to add extra structures to the top surface of the cover plate. Such structures may comprise a surface microstructure (roughness) to affect the flow, for example in terms of thermal accommodation coefficient. These microstructures may have any number of different shapes or dimensions. Such a surface microstructure may comprise a grooved surface in one specific example. In one example, the height of the structures may be in the order of magnitude of a micrometer. In another example they may be on the order of the mean free path of the gas molecules, i.e., up to a few mm. Or they may be any other suitable dimension FIG. 6a shows a chuck arrangement with a cover plate 450′ having such a surface profile.

It is also possible to add macro-structures such as, for example, a rim with a height step or profile around the TIS (or any other sensor) to further reduce the f-factor while the DGL is above the TIS. This is possible as resist contamination is not relevant when the DGL is above the TIS, and consequently the f-factor can be safely reduced. This is the case for when the DGL is above any sensor, and therefore any sensor may benefit from such a rim. FIG. 6b shows a chuck arrangement with a rim 455 around each TIS plate 430.

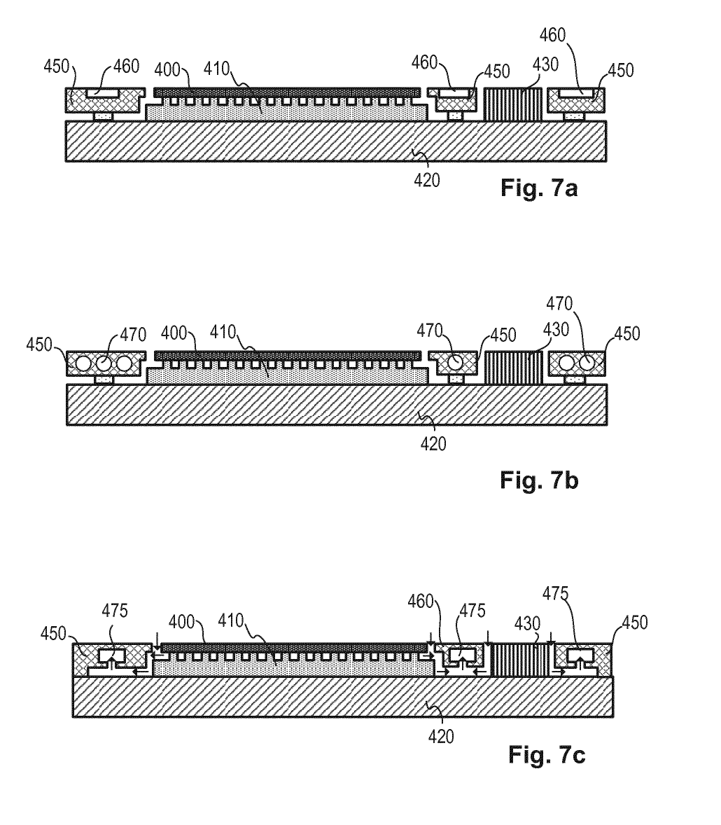

The introduction of a cover plate provides opportunities for further functionality. FIGS. 7a to 7c illustrate three examples where such further functionality has been provided.

FIG. 7a shows an example where further sensors 460 are comprised within the cover plate 450. Such sensors may comprise calibration sensors, temperature sensors, pressure sensors, heat flux sensors and/or contamination sensors (“sniffers”). These sensors are mentioned by way of example only and it should be appreciated that this list is not exhaustive.

FIG. 7b shows an example where the cover plate 450 comprises conditioning elements arranged to provide thermal control, e.g., one or more conditioning conduits 470. Such conditioning conduits may comprise heat pipes or cooling pipes. Alternatively, or in addition the cover plate 450 may comprise local heaters or (Peltier) coolers to adjust local temperatures.

FIG. 7c shows an example where the cover plate 450 provides for gas extraction. The cover plate comprises gas extraction channels 475 for extracting gas (the arrows indicate gas direction during extraction). Gas may be extracted within the plate so as to remove contaminants (both from outgassing and WS) and particles (from wafer table). Gas may also be extracted to remove heat and reduce any temperature difference between cover plate 450 and wafer 400. Another reason to extract gas may be to regulate gas flow in desired directions.

As an alternative to gas extraction, the same cover plate with channels 475 could be used to blow (i.e., the arrows may be reversed). This may be simpler to implement as it is difficult to extract from the wafer table environment due to its low pressure. Such blowing can buffer gaps in the support block assembly surface (e.g., between cover plate 450 and TIS plate 430/wafer 400).

A deliberate gas flow may be provided through the cover plate 450, for example around the TIS plate 430 or elsewhere, in order to mitigate the thermal effects of the downflow from DGL 440 while not exposing wafers.

In order to filter out DUV (deep ultraviolet), or other out-of-band radiation (radiation other than EUV), at the wafer location, it is proposed to incorporate a filter element for filtering DUV and/or out-of-band radiation on the DGL assembly, such as a filter membrane. Such membranes are very thin and can potentially be damaged by venting actions (i.e. actions to introduce air or another type of gas into the machine in order to bring the apparatus to an atmospheric pressure) in the machine. To overcome this issue, a detachable membrane has been proposed. To implement a detachable membrane, a storage location for membrane and the membrane holder should be provided.

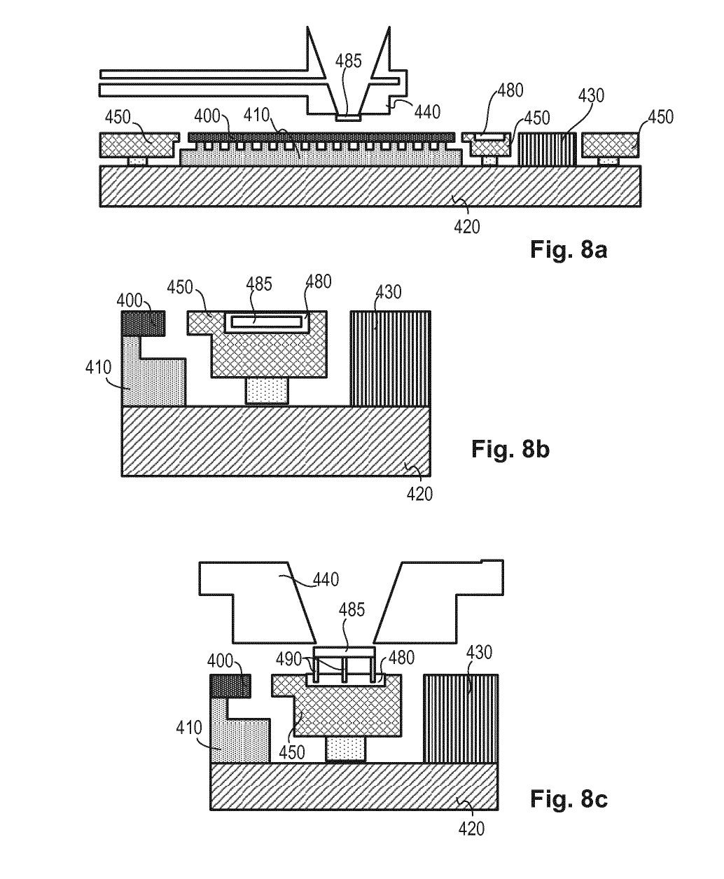

FIG. 8a shows a support block assembly arrangement with such a detachable filter membrane (with holder) 485 located at the DGL 440, and storage enclosure 480 within cover plate 450 for the filter membrane 485. Storing the membrane 485 inside enclosure 480 shields it during wafer stage movements in the vented state, and therefore protects the membrane 485 during venting and other service actions, and while it is clamped in its holder. FIG. 8b shows a detail of the membrane 485 being stored inside enclosure 480.

The membrane and holder 485 can be attached to the DGL 440 during normal operation, for example by (electro) magnets; after being stored in the holder. It may be installed on the DGL by the use of an “e-pins” structure, similar to those used on some wafer tables to aid wafer loading/unloading. E-pins or an e-pins structure is used here to denote a lifting structure to aid in a loading/unloading operation of an object, e.g. to and from an object table. Such a lifting structure may include one or more elongated elements such as pins which can selectively extend from the upper surface of the wafer table or object table during unloading thereby lifting the wafer or object, and retract flush with or below the wafer table's upper surface at other times.

FIG. 8c illustrates a specific example of attaching the membrane 485 to the DGL 440 using e-pins 490. In this example, three e-pins are provided, (although different numbers are possible). The e-pins 490 are comprised within a ring (“e-ring”), conformal with the periphery of the membrane holder. The e-pins 490 extend to push the membrane 485 toward the DGL 440, so as to deploy it (for example magnetically, such that one of the DGL or membrane holder comprises one or (electro) magnets to attract the other of the DGL or membrane holder).

It is envisaged, optionally, to have redundant (e.g., two or more) enclosures 480 in the cover plate such that there is a spare membrane 485 available in case of failure, and therefore physical replacement can be postponed until the next service action.

While the above embodiments have shown the cover plate as separate to the support block it is supported by, it should be appreciated that the cover plate and support block may be a single integral unit.

Also, while the thermal effect of the down flow from DGL is one of the main components of the heat load on the wafer stage, it may be desirable to balance other heat load components to achieve a better thermal uniformity along the entire wafer stage.

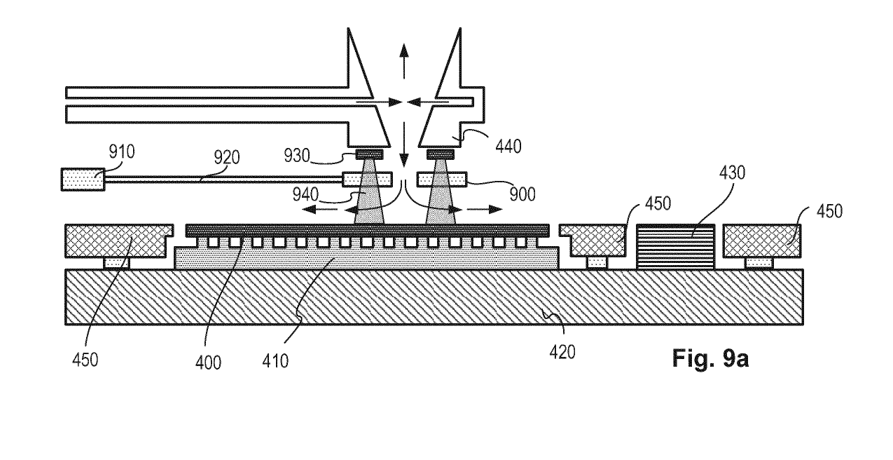

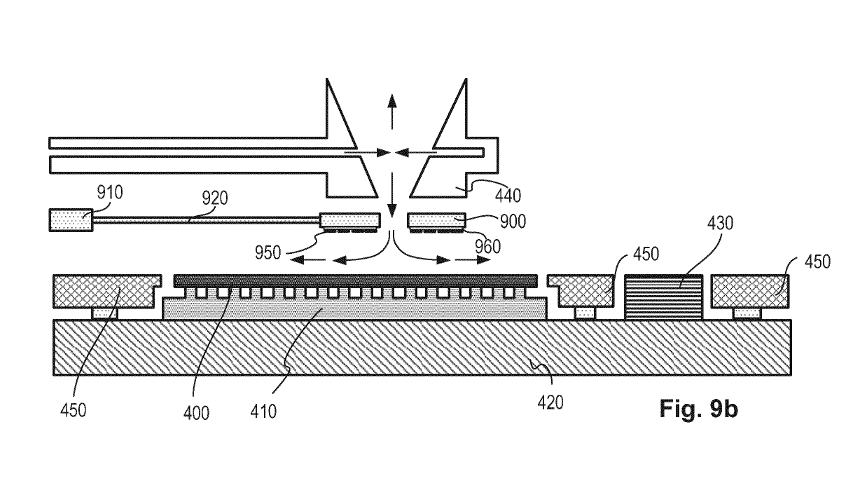

FIGS. 9a and 9b show a further embodiment of the EUV wafer stage arrangements shown above. They show a cooling element, such as cooling disk 900, above the wafer 400. The cooling disk 900 is maintained at a low temperature by Peltier cooler 910 and heat pipe 920 (cooling of the cooling disk 900 may be performed by alternative means). Also shown is fast switching active heating devices for providing localized heating. In the specific example shown in FIG. 9a, the heating devices comprise LED sources 930 emitting radiation 940. However, other devices may be used provided that they are sufficiently fast switching. For example a MEMS device could be used instead. FIG. 9b shows an alternative heating arrangement where fast switching, thin film heaters 950 are used. Between the thin film heaters 950 and cooling disk 900 is an insulation material 960.

The wafer is subject to heat loads which result in wafer deformation. It has been shown that these heat loads are not uniform over the wafer, but rather successive regions are subject to alternate higher and lower heat loads. This effect is largely driven by the scan pattern and the switching on and off of the heat load. The result is a characteristic “chess board” pattern of regions on the wafer which alternate between different measured overlay figures. For example, regions displaying approximately +2 nm measured overlay may be seen to alternate with regions displaying approximately −2 nm measured overlay.

The FIGS. 9a and 9b arrangements reduce the wafer deformation by directly conditioning the wafer temperature, rather than doing this via the wafer stage. The cooling disk 900 is located above the wafer 400 which is maintained at a low temperature (e.g., less than 10 degrees C., possibly less than 5 degrees C.). Consequently the cooling disk 900 imparts a (constant) negative heat load on the wafer. This negative heat load causes a heat flow away from the wafer 400, and towards the cooling disk 900, removing energy from the wafer 400. One heat transfer mechanism is convection via the gas medium between the cooling disk and wafer surface which results from the DGL gas flow. Another heat transfer mechanism is radiation. With regard to the latter, consideration should be given to the emissivity of the cooling disk 900. Providing the cooling disk 900 with a high emissivity coating increases the heat transfer and therefore the magnitude of the negative heat load. However this means that temperature sensors are required to adapt the temperature of the disk, as the emissivity of wafer can vary for different exposed layers. Alternatively, a low emissivity coating can be used on the cooling disk 900. This helps make the configuration robust for varying emissivities of the wafer layers.

This cooling disk 900 helps prevent ‘first-wafer-effects’. Such effects are those resultant from different thermal conditions which can be experienced during a first measure-expose cycle after rest and subsequent measure-expose cycles. For each measure-expose cycle after the first, residual heat from the previous cycle may affect wafer temperature differently compared to that experienced during the first cycle. This may happen when 3 times τ is larger than the time between exposures, the thermal time constant τ representing the time it takes the system's step response to reach 1-1/e˜63.2% of its final (asymptotic) value. This means that there is the possibility of different clamp behavior between the first layer and other layers, resulting in an overlay penalty. The cooling disk reduces the net energy on the table which omits the need for aggressive cooling in the clamp (which can cause flow-induced vibrations from the cooling medium flow), or even active control segments in the clamp.

However the constant (DC) behavior of the negative heat load and the switching behavior of the EUV expose load means that the chess-board pattern will remain when using the cooling disk 900 alone. This issue is addressed by the LED switchable heating sources 930, 950, which provide active, fast switched and direct heating of the wafer during times when the expose heat load is low or off. Note that, as an alternative to providing a direct heating of the wafer, the LED switching heat sources may also be configured to provide a local heating of the cooling disc 900. To compensate for this additional positive heat load, the cooling disk 900 should impart a larger negative load compared to that required if being used without the active heating. This can be done (for example) by increasing the disk 900 area, maintaining the disk 900 at a lower temperature or increasing the DGL gas flow (and hence gas pressure between disk 900 and wafer 400). In the example of the thin film heating sources 950, this negative heat load may be made larger than with the example of the LED heating sources 930, to compensate for the (fairly small) effect of insulation 960. The switchable heat load can also be applied to the cover plate for a corresponding effect.

The wave-length emitted by the LED heating devices 930 should be chosen such that light is absorbed in the wafer. The LED heating devices 930 are depicted above cooling disk 900 in FIG. 9a. In this example the cooling disk 900 comprises a thin silicon disk which conducts sufficiently to thermally connect the disk surface to the heat-pipe 920 while allowing the radiation 940 to pass though. As an alternative, the radiation beam may be provided from a different angle, such as being provided from the side. Another alternative would be the radiation being emitted from a source on the chuck and reflected off mirrors located on the projection optics box.

The cooling disk 900 embodiments benefit from implementation in conjunction with a cover plate 450 having conditioning conduits 470 for cooling of the cover plate 450 (as illustrated in FIG. 7b). A temperature difference between cooling disk 900 above the wafer and the cover plate 450 at the support block 420 introduces heat flow from cover plate 450 to cooling disk 900. If the cover plate 450 is not cooled it will slowly adapt its temperature. This can potentially cause stresses in the support block 420 through radiation or by expansion of cover plate 450.

In other embodiments, the cooling disk 900 and active heat source 930 is provided without cover plate 450.

While the concepts disclosed herein have been described specifically in combination with LPP sources, they are also applicable to other types of sources, such as DPP sources. Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The term “lens”, where the context allows, may refer to any one or combination of various types of optical components, including refractive, reflective, magnetic, electromagnetic and electrostatic optical components.

The various embodiments of the invention may also be defined by the following clauses:
1. A substrate support for an apparatus of the type which projects a beam of radiation having a wavelength in the EUV range or smaller, onto a target portion of a substrate, said substrate support comprising:
   a substrate table constructed to hold a substrate;
   a support block for supporting said substrate table;
   at least one sensor unit; and
   a cover plate disposed around said substrate table and said sensor unit(s), said cover plate being located and configured to cause an increased resistance to a gas flow upon the substrate table.
2. A substrate support according to clause 1 configured such that the top surface of the cover plate, the top surface of said sensor unit(s) and the top surface of a substrate when mounted on said substrate table are all substantially at the same level.
3. A substrate support according to clause 1 or 2 wherein one or more of the at least one sensor units is supported by the support block.
4. A substrate support according to clause 1 or 2 wherein one or more of the at least one sensor units is mounted within the cover plate.
5. A substrate support according to any preceding clause, wherein the cover plate comprises apertures in its top surface for said substrate table and said sensor unit(s).
6. A substrate support according to any preceding clause wherein the cover plate comprises a rim with a raised or stepped profile around the sensor unit(s).
7. A substrate support according to any preceding clause wherein said sensor unit(s) include one or more of positioning sensor units, alignment sensor units, calibration sensor units, temperature sensor units, pressure sensor units, heat flux sensor units and/or contamination sensor units.
8. A substrate support according to any preceding clause wherein the cover plate is separate to, and supported by, the support block.
9. A substrate support according to any of the clause 1 to 7 wherein the cover plate and support block comprises a single integral unit.
10. A substrate support according to any preceding clause wherein said cover plate comprises conditioning elements.
11. A substrate support according to clause 10 wherein said conditioning elements comprise one or more conduits for carrying a heat exchange fluid.
12. A substrate support according to any preceding clause wherein said cover plate comprises means for establishing a gas flow between an area immediately above said cover plate and one or more conduits within or beneath the cover plate.
13. A substrate support according to clause 12 wherein said gas flow is operable to blow gas through a gap between the cover plate and said substrate mounted on the substrate table and/or a gap between the cover plate and any sensor unit(s) so as to act as a buffer.
14. A substrate support according to clause 12 wherein said gas flow is operable to extract gas into said one or more conduits from the area immediately above said cover plate, via a gap between the cover plate and said substrate mounted on the substrate table and/or a gap between the cover plate and any sensor unit(s).
15. A substrate support according to any preceding clause wherein the top surface of the cover plate comprises a surface microstructure.
16. A substrate support according to clause 15 wherein the surface microstructure comprises a grooved surface.
17. A substrate support according to any preceding clause wherein the top surface of the cover plate comprises one or more macro-sized structures.
18. A substrate support arrangement comprising:
   a substrate support according to any preceding clause; and
   a cooling element located above said substrate support and operable to impart a direct negative heat load on a substrate supported by said substrate support.
19. A substrate support arrangement according to clause 18 wherein the cooling element is located so as to at least partially confine a gas between the cooling element and substrate surface, said gas acting as a medium for heat transfer from substrate to cooling element.
20. A substrate support arrangement according to clause 18 or 19 wherein the cooling element comprises a silicon disk.
21. A substrate support arrangement according to clause 18, 19 or 20 comprising one or more switchable heating sources being operable to provide a localized, switchable heat load on a substrate supported by said substrate support.
22. A substrate support arrangement according to clause 21 wherein the heating source is located above said cooling element such that radiation emitted by said heating source is transmitted through the cooling element.
23. A substrate support arrangement according to clause 21 or 22 wherein the heating source comprises a light emitting diode device operable to emit a beam for locally heating said substrate.
24. A substrate support arrangement according to clause 21 or 22 wherein the heating source comprises a microelectromechanical (MEMS) device operable to emit a beam for locally heating said substrate.
25. A substrate support arrangement according to clause 21 wherein said heating source comprises a thin film heater.
26. A substrate support arrangement according to any of the clauses 21 to 25 wherein the heating source is operable to locally heat portions of said substrate during periods when no beam of said radiation having a wavelength in the EUV range or smaller is being projected onto said substrate.
27. A substrate support arrangement for an apparatus of the type which projects a beam of radiation having a wavelength in the EUV range or smaller, onto a target portion of a substrate, comprising:
   a substrate support constructed to hold a substrate;
   a cooling element located above said substrate support and operable to impart a direct negative heat load on a substrate supported by said substrate support; and
   one or more switchable heating sources being operable to provide a localized, switchable heat load on a substrate supported by said substrate support.
28. A substrate support arrangement according to clause 27 wherein the cooling element is located so as to confine a gas between the cooling element and substrate surface, said gas acting as a medium for heat transfer from substrate to cooling element.
29. A substrate support arrangement according to clause 27 or 28 wherein the cooling element comprises a silicon disk.
30. A substrate support arrangement according to clause 29 wherein the heating source is located above said cooling element such that radiation emitted by said heating source is transmitted through the cooling element.
31. A substrate support arrangement according to any preceding clause 27 to 30 wherein the heating source comprises a light emitting diode device operable to emit a beam for locally heating said substrate.
32. A substrate support arrangement according to any of the clauses 27 to 30 wherein the heating source comprises a microelectromechanical (MEMS) device operable to emit a beam for locally heating said substrate.
33. A substrate support arrangement according to clause 27, 28 or 29 wherein said heating source comprises a thin film heater.
34. A substrate support arrangement according to any of the clauses 27 to 33 wherein the heating source is operable to locally heat portions of said substrate during periods when no beam of said radiation having a wavelength in the EUV range or smaller is being projected onto said substrate.
35. A lithographic apparatus comprising:
   a substrate support according to any of the clauses 1 to 17 or a substrate support arrangement according to any of the clauses 18 to 34;
   a projection system within a projection chamber and configured to project a beam of EUV radiation onto a target portion of a substrate supported by said substrate support; and
   a gas lock mechanism for restricting contaminants entering said projection chamber, while transmitting said beam of EUV radiation from said projection chamber.
36. A lithographic apparatus according to clause 35 wherein said gas lock mechanism, comprises:
   a hollow body including a first end and a second end, said body extending substantially around a path of said beam of EUV radiation from said first end to said second end; and
   a gas flow unit in communication with said body and configured to produce a gas flow within said body, said gas flow restricting contaminants entering said projection chamber, said gas being substantially transmissive for at least part of the EUV radiation.
37. A lithographic apparatus according to clause 35 or 36 wherein said gas lock mechanism comprises a filter element, and said cover plate comprises at least one enclosure for storing said filter element when not deployed.
38. A lithographic apparatus according to clause 37 wherein said enclosure comprises extendable pins for deployment of said filter element on said gas lock mechanism.
39. A lithographic apparatus according to clause 37 or 38 wherein said cover plate comprises a plurality of filter element enclosures.
40. A lithographic apparatus according to any of the clause 35 to 39 wherein said cover plate increases the flow resistance to gas emitted from the gas lock mechanism when the support is positioned such that the cover plate is directly below the gas lock mechanism, compared to the flow resistance encountered without a cover plate when the support is in the same position.
41. A lithographic apparatus as claimed in any of clauses 35 to 40 wherein the flow resistance to gas emitted from the gas lock mechanism is substantially constant over the top surface of the substrate support, away from its periphery.
42. A lithographic apparatus according to any of the clauses 35 to 41, further comprising:
   a radiation source configured to generate a beam of EUV radiation;
   an illumination system configured to condition the radiation beam; and
   a support constructed to support a patterning device, the patterning device being capable of imparting the radiation beam with a pattern in its cross-section to form a patterned radiation beam.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1. A substrate support for an apparatus of the type which projects a beam of radiation having a wavelength in the EUV range or smaller, onto a target portion of a substrate, the substrate support comprising:
a substrate table constructed to hold a substrate;
a support block configured to support the substrate table;
at least one sensor unit; and
a cover plate disposed around the substrate table and the at least one sensor unit, the cover plate being located and configured to cause an increased resistance to a gas flow upon the substrate table.

2-5. (canceled)

6. The substrate support of claim 1, wherein the cover plate comprises a rim with a raised or stepped profile around the at least one sensor unit.

7-9. (canceled)

10. The substrate support of claim 1, wherein the cover plate comprises conditioning elements.

11. The substrate support of claim 10, wherein the conditioning elements comprise one or more conduits for carrying a heat exchange fluid.

12. The substrate support of claim 1, wherein the cover plate comprises a device configured to establish a gas flow between an area immediately above the cover plate and one or more conduits within or beneath the cover plate.

13. The substrate support of claim 12, wherein the gas flow is operable to blow gas through a gap between the cover plate and the substrate mounted on the substrate table or a gap between the cover plate and the at least one sensor unit so as to act as a buffer.

14. The substrate support of claim 12, wherein the gas flow is operable to extract gas into the one or more conduits from the area immediately above the cover plate, via a gap between the cover plate and the substrate mounted on the substrate table and/or a gap between the cover plate and the at least one sensor unit.

15-17. (canceled)

18. The substrate support of claim 1, further comprising:
a cooling element located above the substrate support and operable to impart a direct negative heat load on the substrate supported by the substrate support.

19. The substrate support of claim 18, wherein the cooling element is located so as to at least partially confine a gas between the cooling element and substrate surface, the gas acting as a medium for heat transfer from substrate to cooling element.

20. The substrate support of claim 18, wherein the cooling element comprises a silicon disk.

21. The substrate support of claim 18, comprising one or more switchable heating sources being operable to provide a localized, switchable heat load on the substrate supported by the substrate support.

22. The substrate support of claim 21, wherein the heating source is located above the cooling element such that radiation emitted by the heating source is transmitted through the cooling element.

23. (canceled)

24. The substrate support of claim 21, wherein the heating source comprises a microelectromechanical (MEMS) device operable to emit a beam for locally heating the substrate.

25. (canceled)

26. The substrate support of claim 21, wherein the heating source is operable to locally heat portions of the substrate during periods when no beam of the radiation having a wavelength in the EUV range or smaller is being projected onto the substrate.

27. A substrate support arrangement for an apparatus of the type which projects a beam of radiation having a wavelength in the EUV range or smaller, onto a target portion of a substrate, comprising:
a substrate support constructed to hold a substrate;
a cooling element located above the substrate support and operable to impart a direct negative heat load on the substrate supported by the substrate support; and
one or more switchable heating sources being operable to provide a localized, switchable heat load on the substrate supported by the substrate support.

28. The substrate support arrangement of claim 27 wherein the cooling element is located so as to confine a gas between the cooling element and substrate surface, the gas acting as a medium for heat transfer from substrate to cooling element.

29-33. (canceled)

34. The substrate support arrangement of claim 27, wherein the heating source is operable to locally heat portions of the substrate during periods when no beam of the radiation having a wavelength in the EUV range or smaller is being projected onto the substrate.

35. An apparatus comprising:
a substrate support comprising:
a substrate table constructed to hold a substrate;
a support block configured to support the substrate table;
at least one sensor unit; and
a cover plate disposed around the substrate table and the at least one sensor unit, the cover plate being located and configured to cause an increased resistance to a gas flow upon the substrate table;
an optical system within a chamber; and
a gas lock mechanism for restricting contaminants entering the chamber.

36. The apparatus according to claim 35, wherein the apparatus is a lithographic apparatus; wherein
the optical system within a chamber is a projection system within a projection chamber; the projection system being configured to project a beam of EUV radiation onto a target portion of the substrate supported by the substrate support; and wherein
the gas lock mechanism being configured for restricting contaminants entering the projection chamber, while transmitting the beam of EUV radiation from the projection chamber.

37. (canceled)

38. The lithographic apparatus of claim 35, wherein the gas lock mechanism comprises a filter element, such as a membrane, and the cover plate comprises at least one enclosure for storing the filter element when not deployed.

39-43. (canceled)
